(19) United States
(12) Patent Application Publication
(10) Pub. No.: US 2013/0025021 A1
(43) Pub. Date: Jan. 31, 2013

(54) Tactical Vest

(71) Applicant: A. Vernon Wright, Newport Beach, CA (US)

(72) Inventor: A. Vernon Wright, Newport Beach, CA (US)

(21) Appl. No.: 13/239,297

(22) Filed: Sep. 21, 2011

Related U.S. Application Data
(60) Provisional application No. 61/513,462, filed on Jul. 29, 2011.

(51) Int. Cl. A41D 1/04; H02J 7/00; H01L 31/048

(52) U.S. Cl. 2/102; 136/251; 320/101

(57) ABSTRACT

A tactical vest can comprise a body garment, a solar collector mounted on the body garment, and a power interface coupled to the solar collector operable to store power collected from the solar collector and distribute power to rechargeable devices that can be connected to the power interface.

### BACKGROUND

Various electrical and electronic devices are powered by rechargeable batteries that need to be charged periodically.

A disadvantage of such devices is lack of an available power source in various circumstances and conditions. For example, military personnel in the field, adventure enthusiasts such as climbers and hikers, people who are in the field for extended times, and the like may often be unable to receive power for recharging devices.

### SUMMARY

Embodiments of a tactical vest can comprise a body garment, a solar collector mounted on the body garment, and a power interface coupled to the solar collector operable to store power collected from the solar collector and distribute power to rechargeable devices that can be connected to the power interface.

### BRIEF DESCRIPTION OF THE DRAWINGS

Embodiments of the invention relating to both structure and method of operation may best be understood by referring to the following description and accompanying drawings:

FIG. 1 is a schematic pictorial diagram showing an embodiment of a solar-powered vest;

FIGS. 2A, 2B, 2C, and 2D are schematic block diagrams illustrating an embodiment of a power management apparatus operable to regulate power to an attached powered device according to power requirements of the device; and

FIG. 3 are schematic pictorial views showing steps of an embodiment of a technique for producing solar modules.

### DETAILED DESCRIPTION

A tactical vest can be configured for military and commercial applications with solar power collection capability to enable charging of rechargeable devices in the field.

In various configurations, the vest can supply suitable power for charging field devices such as mobile telephones, notebook and handheld computers, and the like. The vest can supply, for example, 9-25 volts in various embodiments. In some embodiments, the vest can attain 25 volts with a relatively small footprint of solar collection, such as 12″×15″.

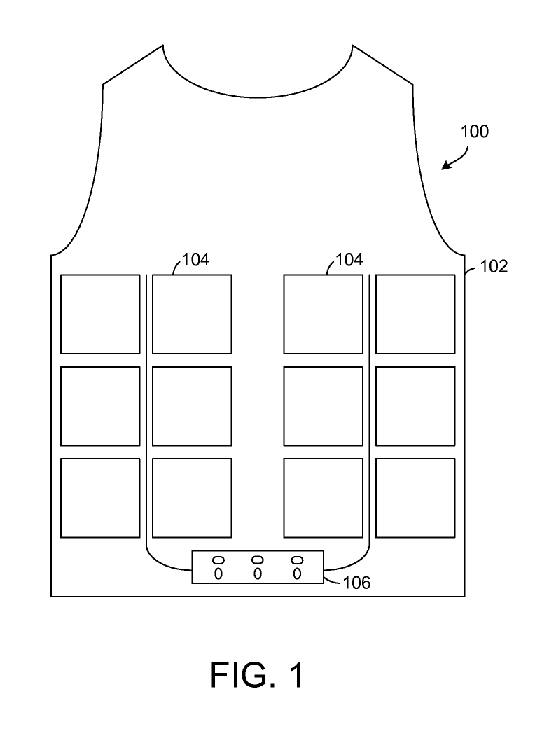

Referring to FIG. 1, a schematic pictorial diagram shows an embodiment of the vest 100 which can comprise a body garment 102, a solar collector 104 mounted on the body garment 102, and a power interface 106 coupled to the solar collector operable to store power collected from the solar collector and distribute power to rechargeable devices that can be connected to the power interface.

The vest can be used to charge any item of equipment in the field.

When in use, the vest can simultaneously charge one or more rechargeable devices.

The solar collector can comprise a carbon fiber sheet, a plurality of solar cells mounted on the carbon fiber sheet, and a coating applied in multiple layers on the plurality of solar cells and the carbon fiber sheet.

In a particular embodiment, the solar cells can be monocrystalline cells.

In some embodiments, the voltage supplied by the solar collector can be raised above conventional levels, for example to 25 volts in some embodiments, by processing the monocrystalline solar cell with a particular configuration of cuts and assembly. In this manner, the monocrystalline cell can be processed to enable production of selected voltage and amperage, rather than attempting to attain a particular wattage.

In an illustrative embodiment, the solar collector can be arranged in cells, for example “6×6” monocrystalline cells mounted on carbon fiber. The moncrystalline cells can be cut to protect solder lines and prevent short-circuiting. Cutting the monocrystalline cells can improve efficiency. In an example configuration an efficiency of 68-71% was attained. Cutting the monocrystalline cell is believed to attain increased power through a “rebound effect” wherein photons rebound in the carbon fiber to create additional power. The monocrystalline cells are cut into chips and mounted on the carcon fiber, and the cells are soldered to maximize power. The carbon fiber acts as insulation. The monocrystalline cells are electrically connected along a bus line which is also mounted on the carbon fiber. Photons rebounding in the carbon fiber. Photons are believed to reflect in multiple layers in the non-conductive carbon fiber.

The electrical energy collected by the solar collector can be stored in a solar-charged lithium polymer battery which achieves more rapid charging and resistance to explosion.

Embodiments of the tactical vest can include a power interface that include a power management apparatus which is operable to regulate power to an attached powered device according to power requirements of the device.

The power management apparatus enables recharging of devices via a jack, such as an audio jack, a universal serial bus (USB) connector, and others. Accordingly, the vest can be used to charge mobile telephones, computers, or any other suitable rechargeable device.

Some embodiments of the power management apparatus can safely recharge devices with a wide range of electrical and power characteristics.

Some embodiments of the power management apparatus can be powered remotely from grid electrical power, for example via solar or battery energy, to enable field usage.

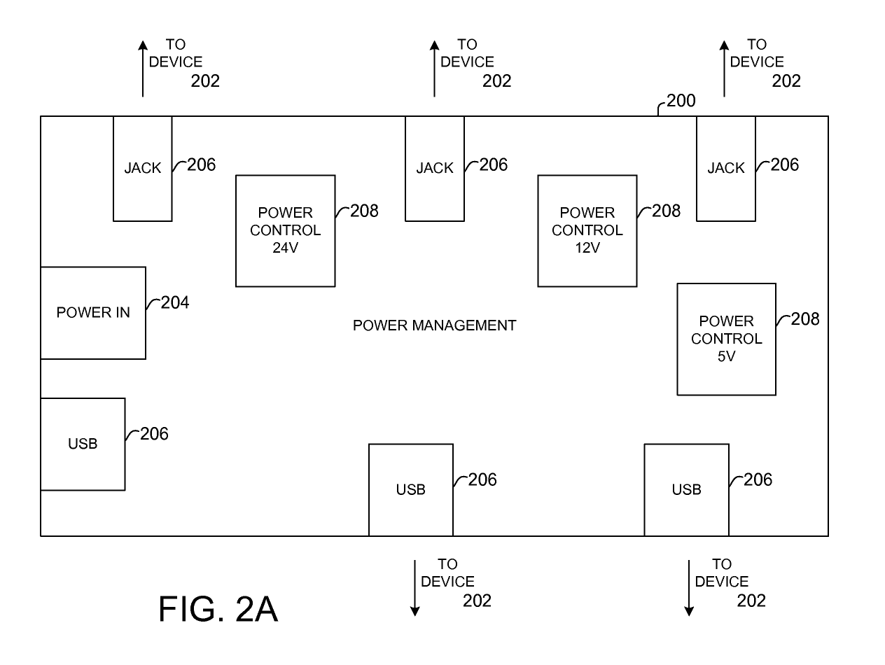

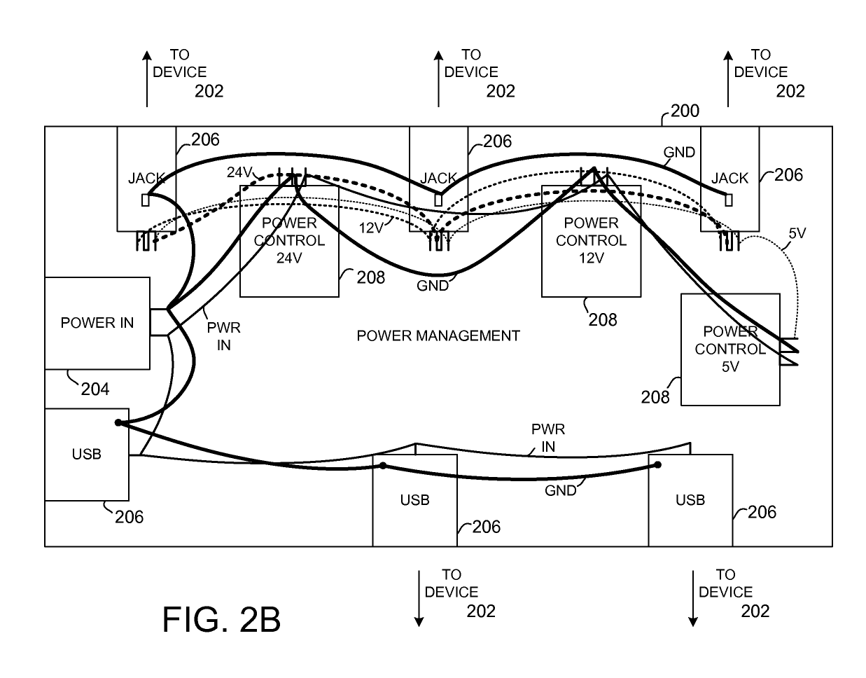

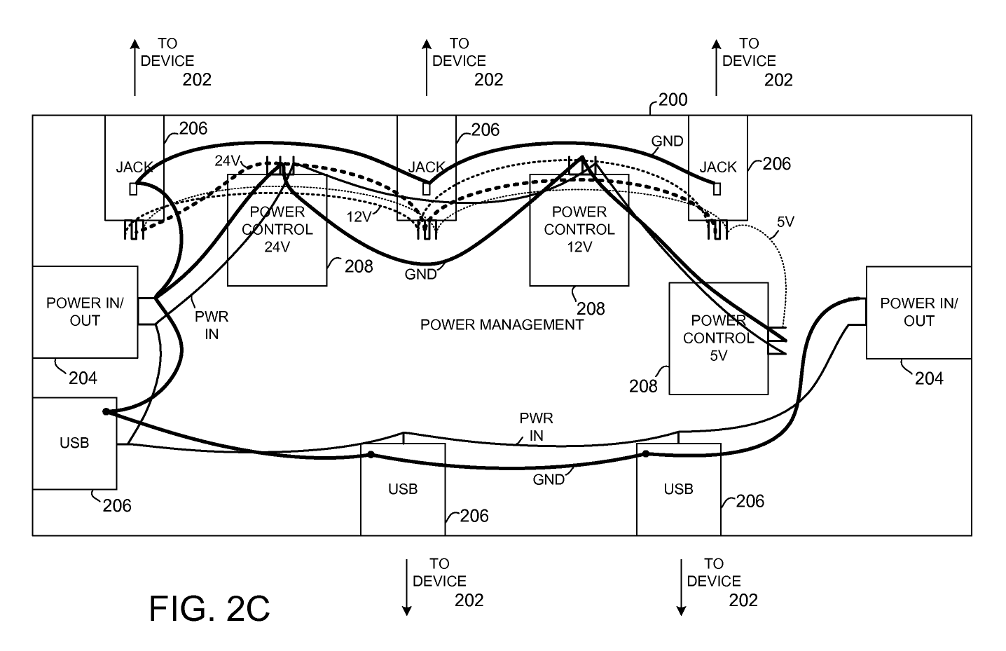

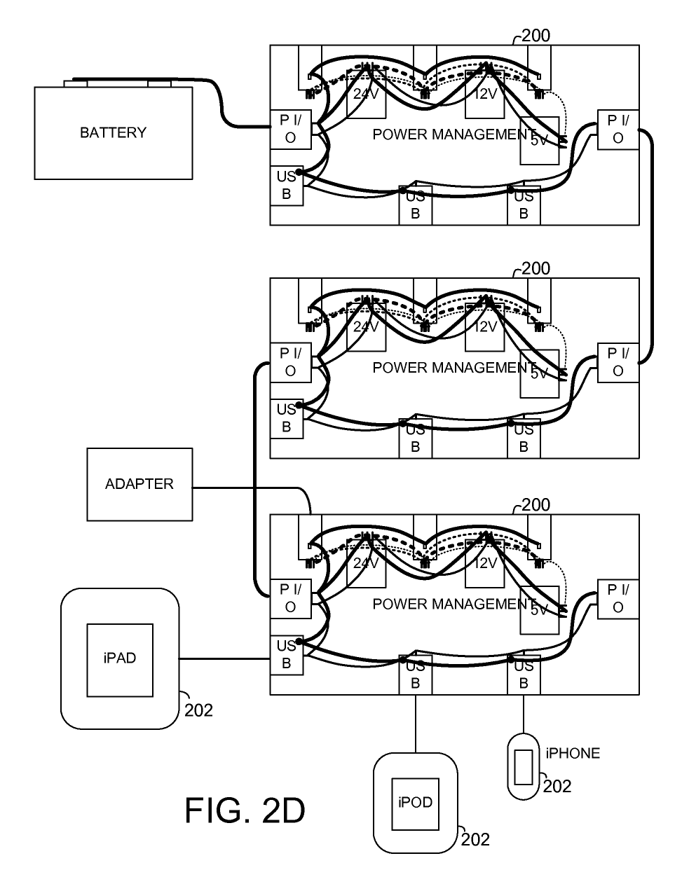

Referring to FIGS. 2A, 2B, 2C, and 2D, schematic block diagrams illustrate embodiments of a power management apparatus 200 operable to regulate power to an attached powered device 202 according to power requirements of the device 202. The illustrative power management apparatus 200 can comprise a power input connector 204, at least one power output connector 206, and at least one power control circuit 208. The at least one power output connector 206 is operable to supply power to powered devices 202 characterized by a plurality of power characteristics. The at least one power control circuit 208 is operable to determine a power characteristic of a powered device 202 connected to the at least one power output connector 206 and to supply power to the powered device 202 in compliance with the power characteristic.

In some embodiments, the at least one power output connector 206 can comprise at least one Universal Serial Bus (USB) connector.

In some embodiments, the at least one power output connector 206 can comprise at least one connector jack.

In some embodiments, the at least one power output connector 206 can comprise at least one audio output jack.

In some embodiments, the at least one power output connector 204 can comprise at least one Universal Serial Bus (USB) connector and at least one connector jack.

In some embodiments, the at least one power output connector 206 can comprise at least one output connector operable to connect a plurality of powered devices in series as shown in FIGS. 2C and 2D.

In other embodiments, the power output connectors 206 can be any suitable connector.

In some embodiments, the power input connector 204 can be operable for connecting to a solar power source.

In some embodiments, the power input connector 204 can be operable for connecting to a battery.

In some embodiments, the power input connector 204 can be operable for connecting to any suitable power source including, for example, line power, a generator, and the like.

In some embodiments, the at least one power control circuit 208 can be operable to determine a power requirement of a powered device connected to the at least one power output connector and to regulate power to the determined power requirement.

For example, the power control circuit 208 can read the pins of a USB device connected to a power output connector 206 to determine power characteristics of the USB device.

In some embodiments, the at least one power control circuit 208 can comprise blocking diodes operable to restrict power for charging the powered device.

In some embodiments, the at least one power control circuit 208 can be operable to determine a voltage requirement of a powered device connected to the at least one power output connector and to regulate voltage to the determined requirement.

In some embodiments, the at least one power control circuit 208 can be operable to determine a current requirement of a powered device connected to the at least one power output connector and to regulate current to the determined requirement.

In an example embodiment, the power management apparatus 200 can be a Power Management System (PMS) configured in a small chassis, for example a housing or box of dimensions 3″×2″×1″ and weighing about 5 oz, although any suitable size and weight may be selected. The PMS can be used to replace an 8 to 9 pound laptop size device which permits powered devices, such as Military Field Units in a military application, to be plugged into a recharging station. The reduced size and weight of the PMS can enable a user, such as military personnel, to carry two (2) or more to charge between 6 to 12 radios, night vision optical devices, Global Positioning System (GPS), Satellite telephones, computers, cell phones, laser designators, and the like.

In an example embodiment, the power management apparatus 200 and all powered devices can be charged using a solar power source such as a “Solar Vest” panel which can supply, for example, provides 25 volts of power. Similarly, some embodiments of the power management apparatus 200 and all powered devices can be charged using a battery “Brick” which generates 20 volts of power.

In some embodiments, the power control circuit 208 can be micro-circuit chips which can attach to USB or stereo speaker jacks. The micro-circuit chips determine the power required by a device needing charged and regulate the output charge to the recognized power requirement. In example configuration of the power management apparatus 200 can simultaneously supply multiple voltages. For example, in a military application, the military typically imposes three (3) recharge requirements: 5 v, 12 v and 24 v, as shown in FIG. 2B. The micro-chip can detect the power requirement and then with blocking diodes restrict the amount of power used to charge the device. The PMS can have a power-out to permit a number of devices to be operated in series.

In a military application, military personnel using the PMS is preventing from using an incorrect power amount because the micro-circuits can detect the proper amperage, then block any higher power. The PMS can be used in military or commercial applications to regulate and control the amount of amperage needed by multiple devices simultaneously. The PMS can use micro-circuitry to automatically detect the proper amperage.

Although any suitable battery can be used to power the PMS, in some applications a Lithium Polymer battery can be used.

Solar Collector.

Embodiments of a solar module or panel comprise solar cells mounted on carbon fiber and coated with a multiple-layer spray coat of a material such as polyvinyl alcohol. The carbon fiber can improve solar-to-electricity conversion by reducing heat loss. The coating can improve efficiency by enhancing incident light on the photovoltaic cells. The produced structure also can increase durability of the panels.

Process for Preparing Mono Crystalline Cell:

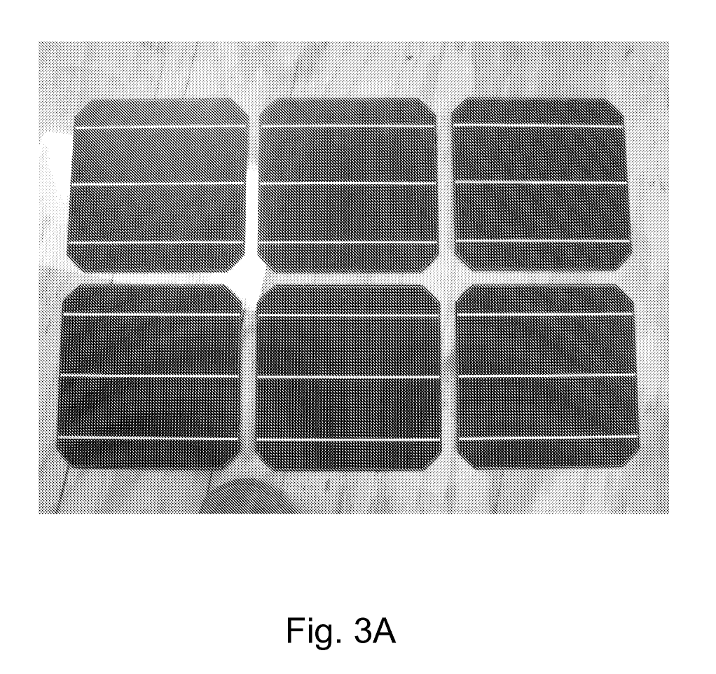

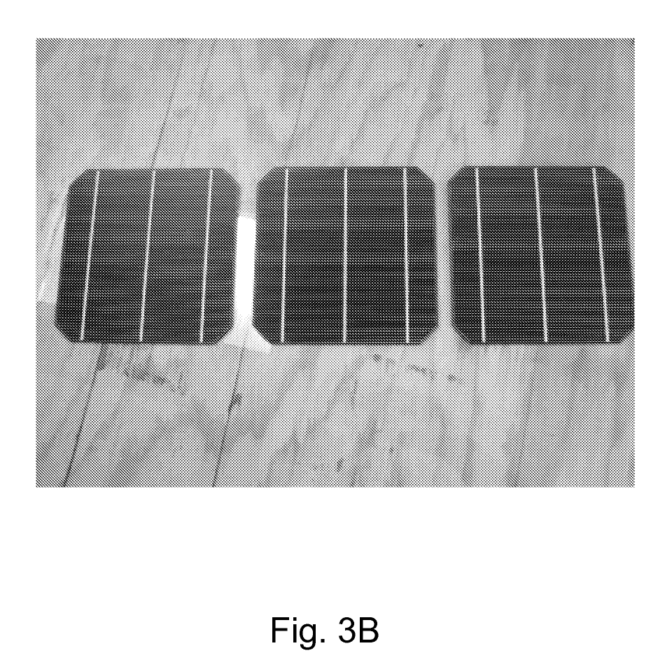

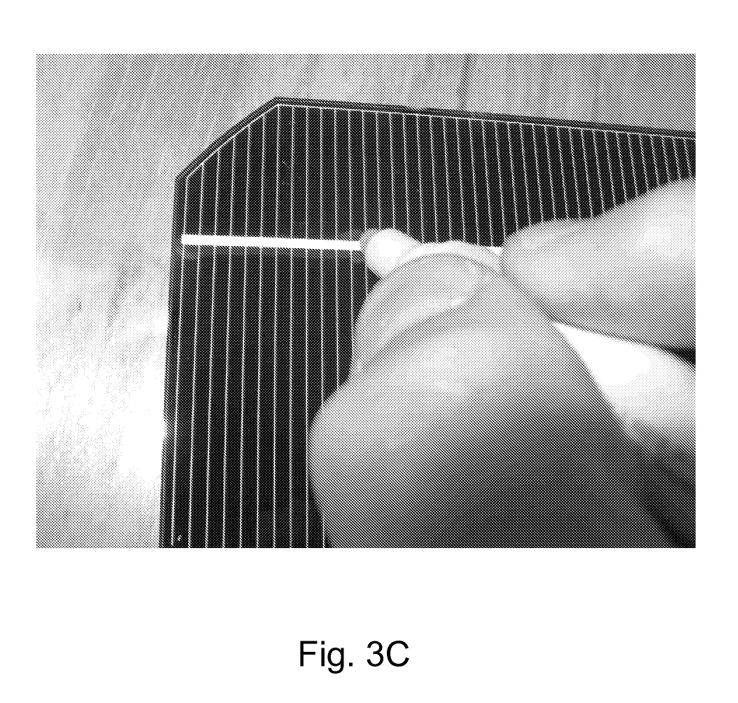

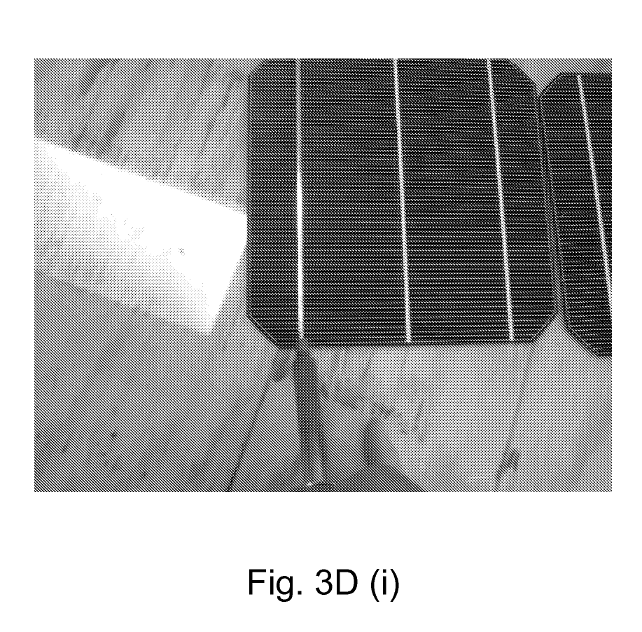

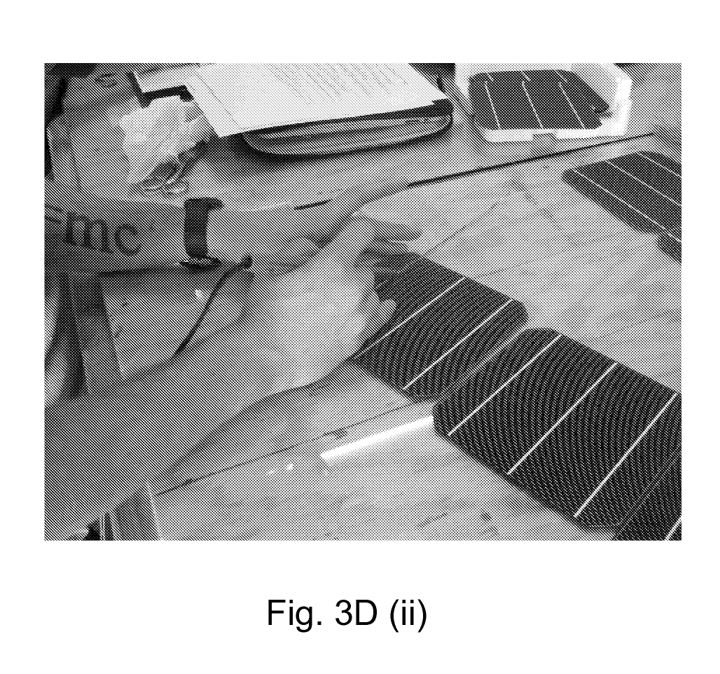

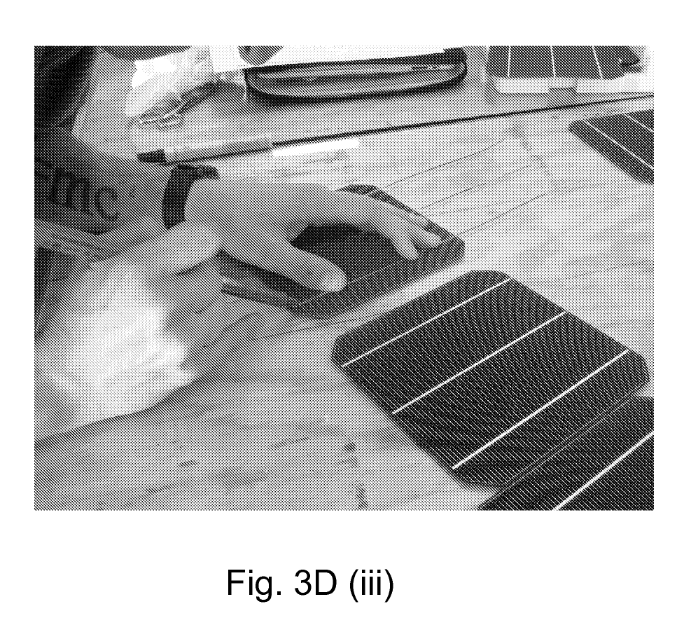

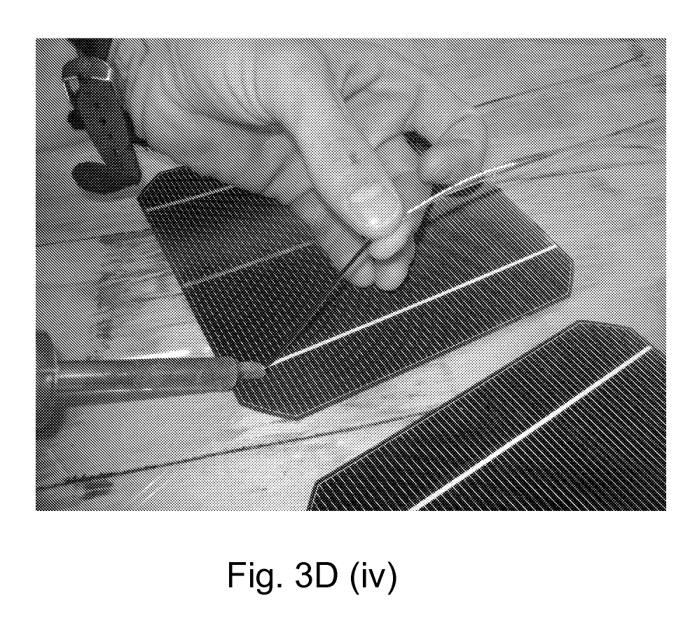

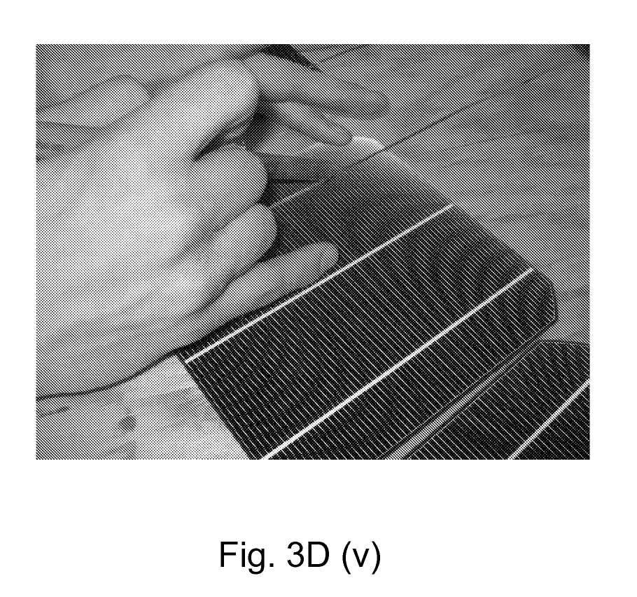

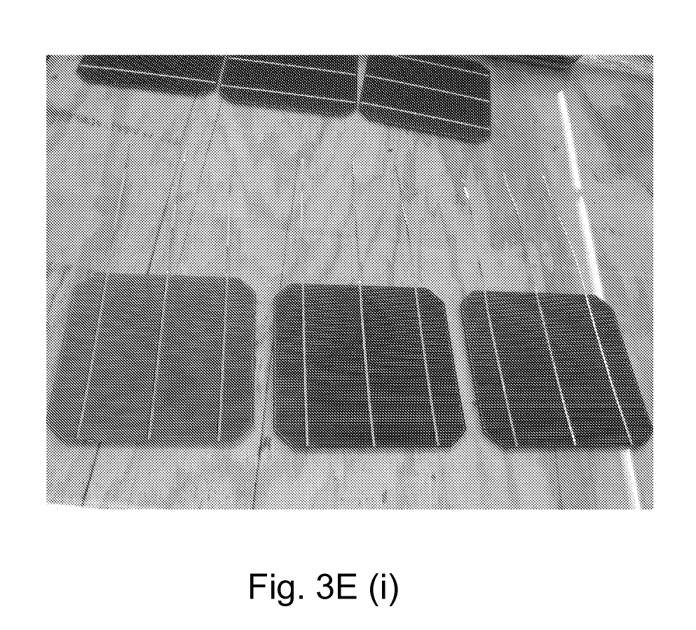

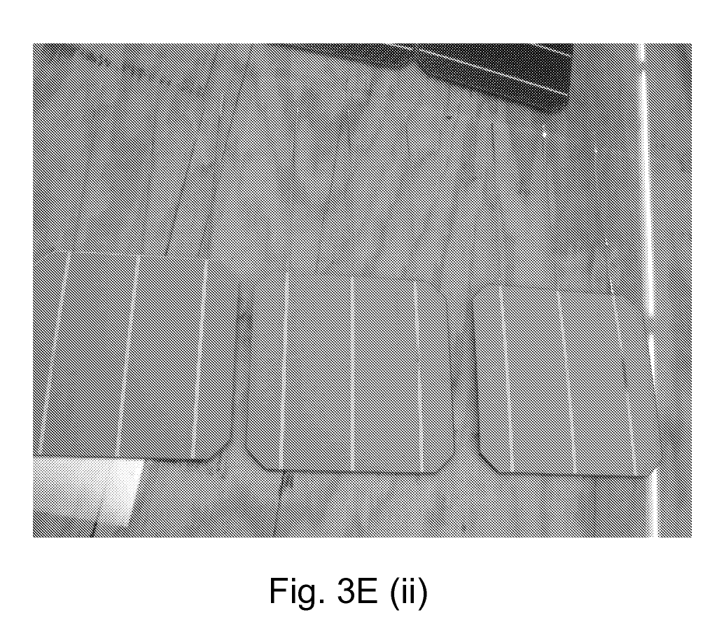

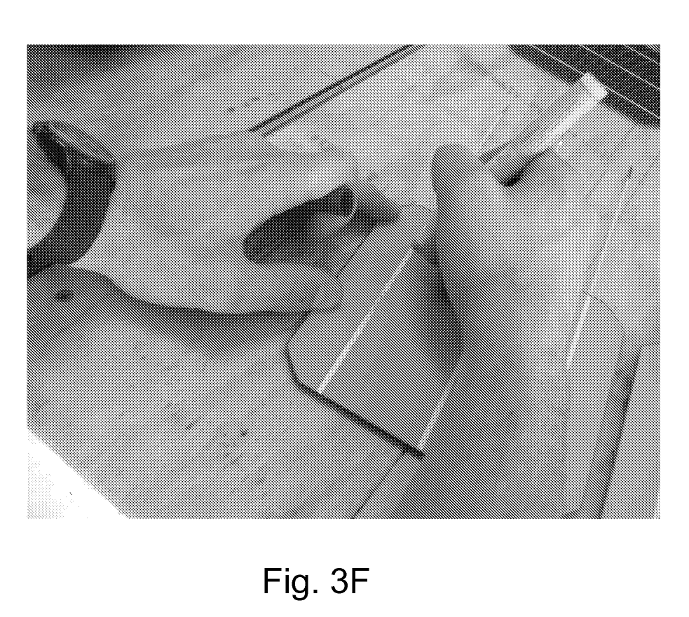

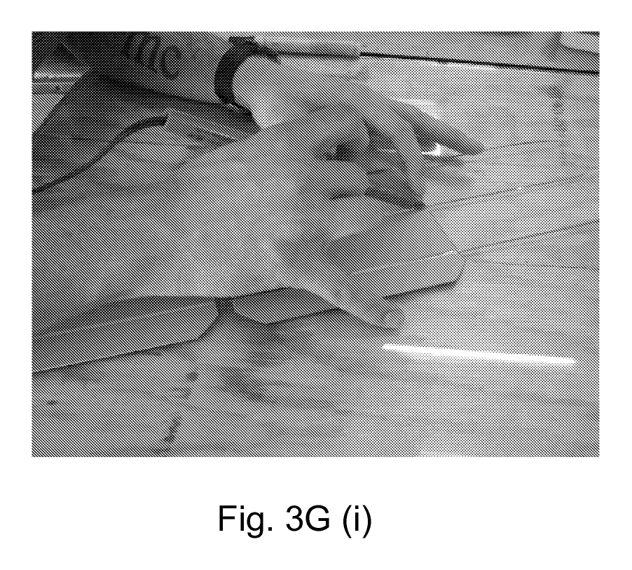

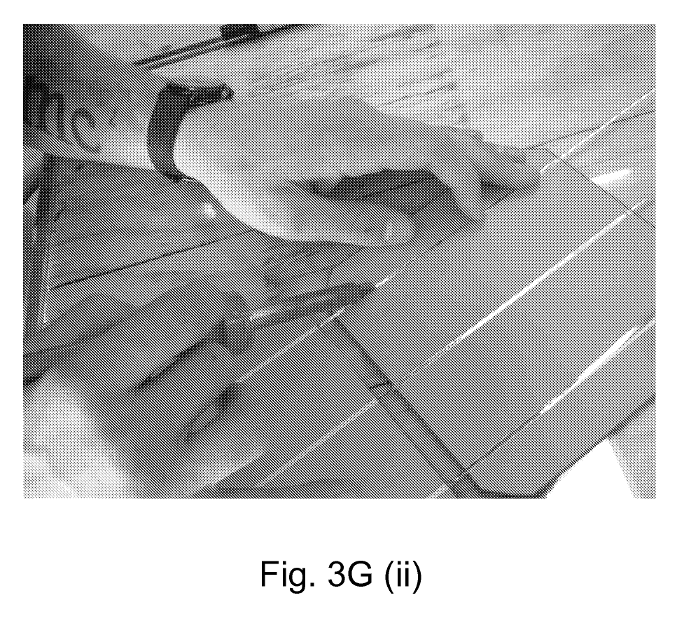

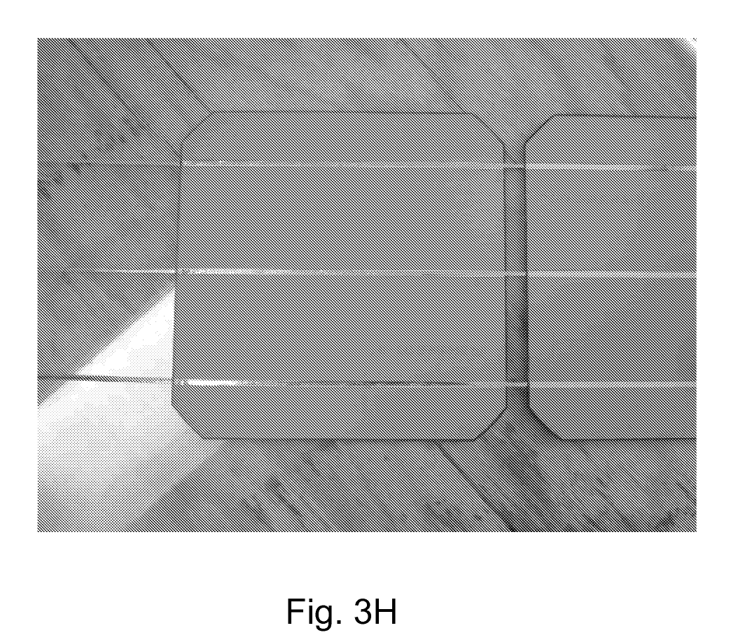

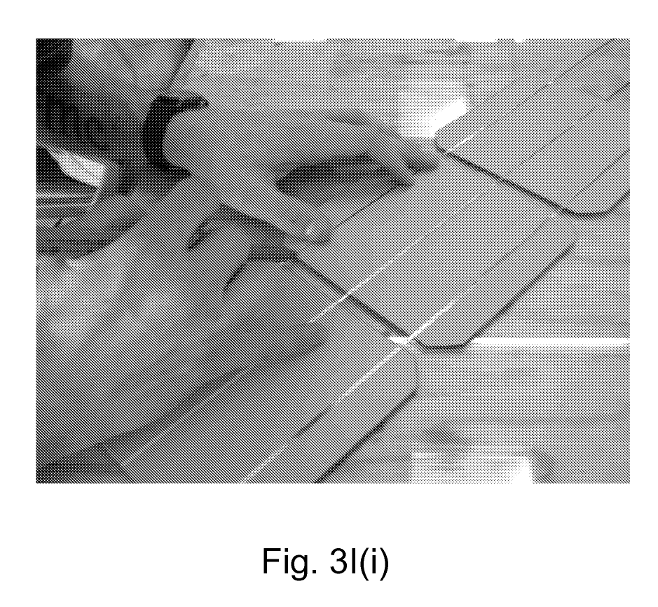

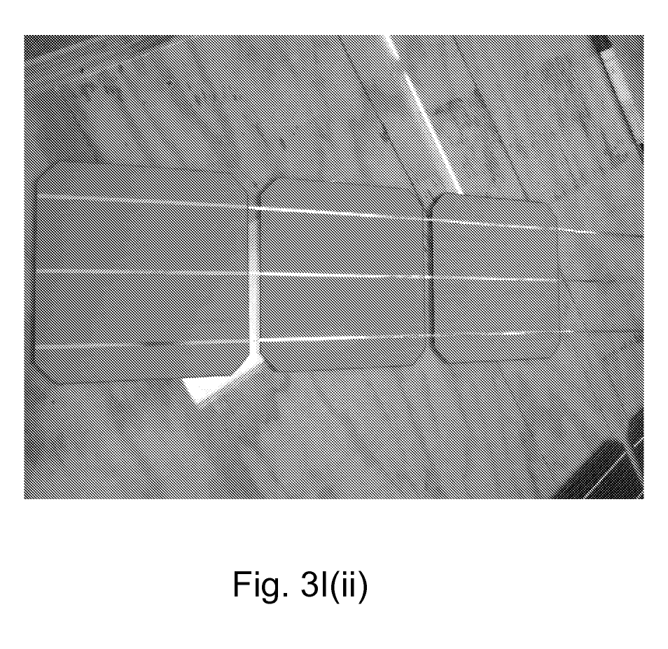

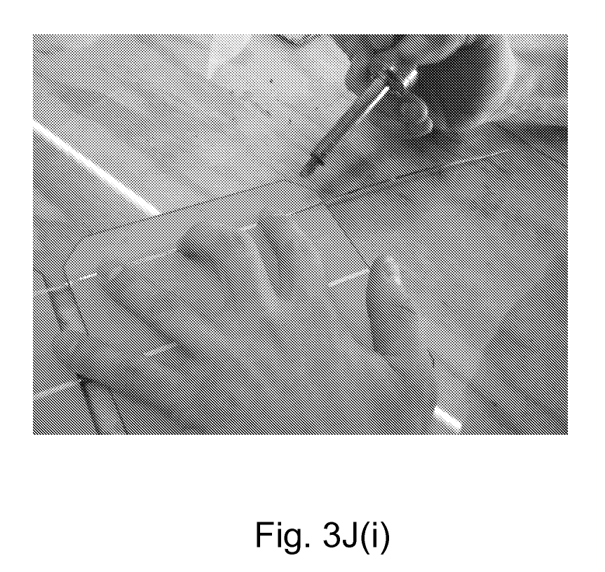

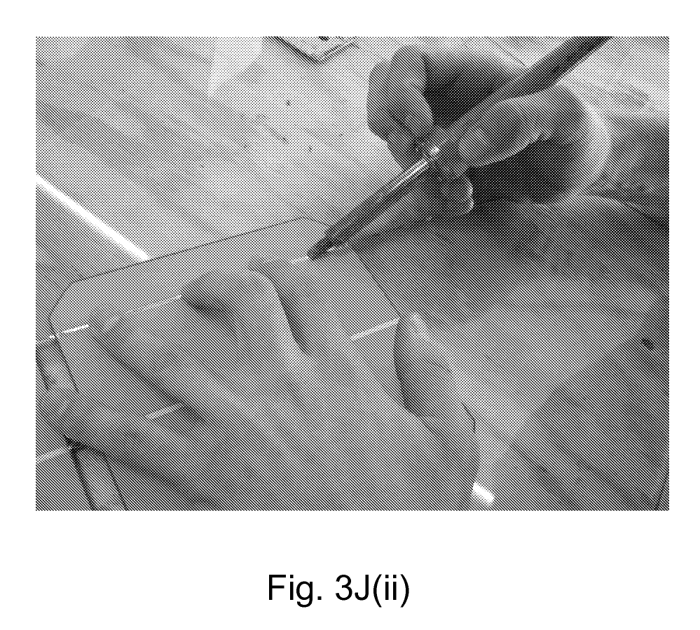

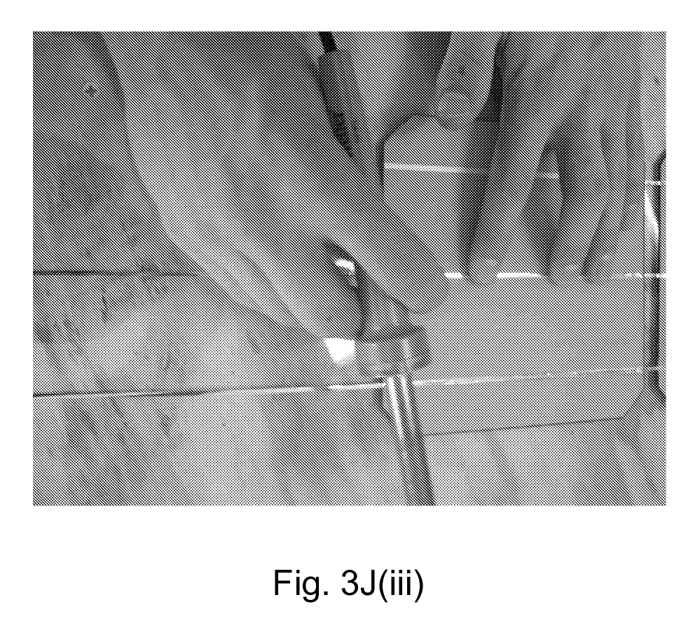

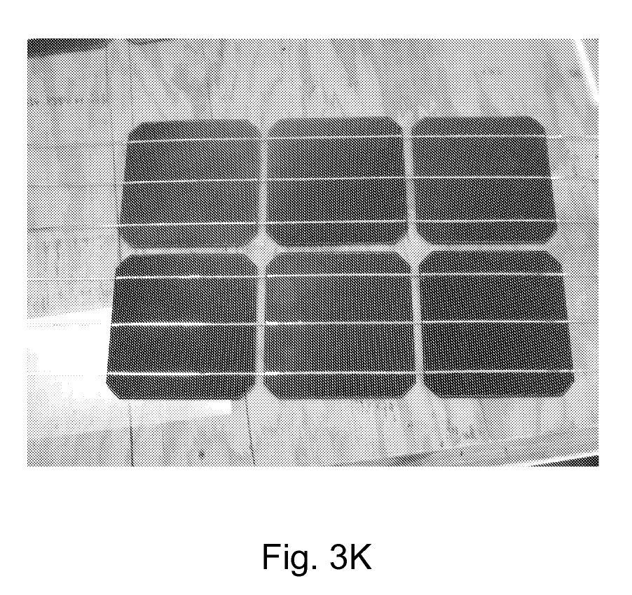

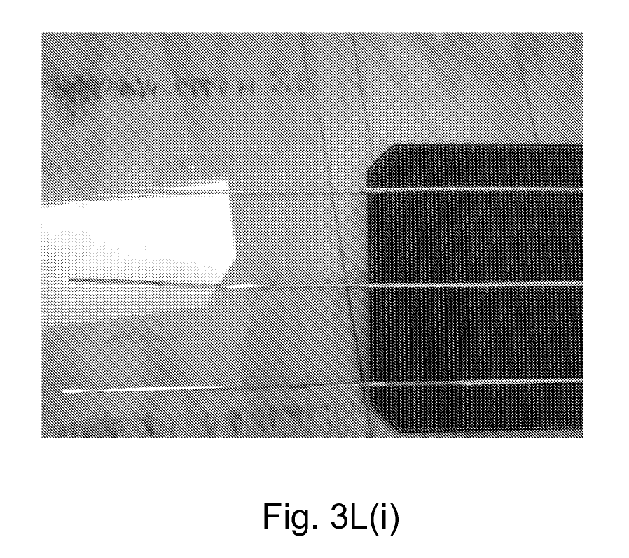

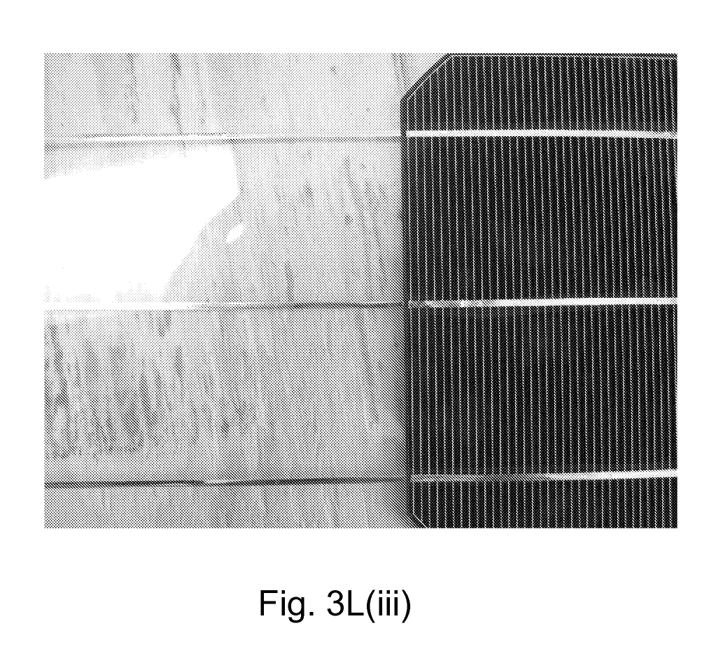

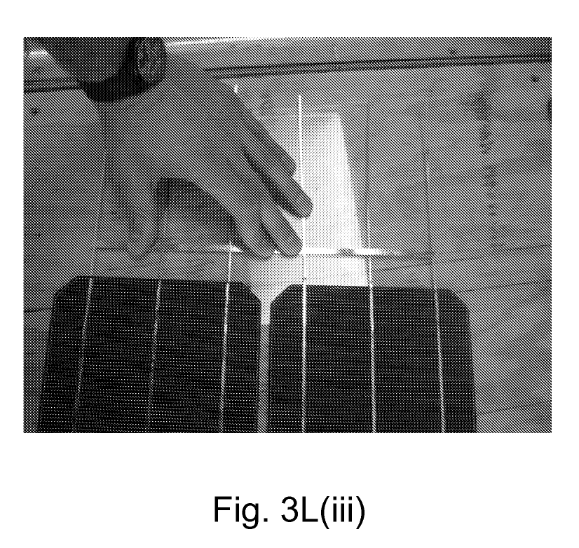

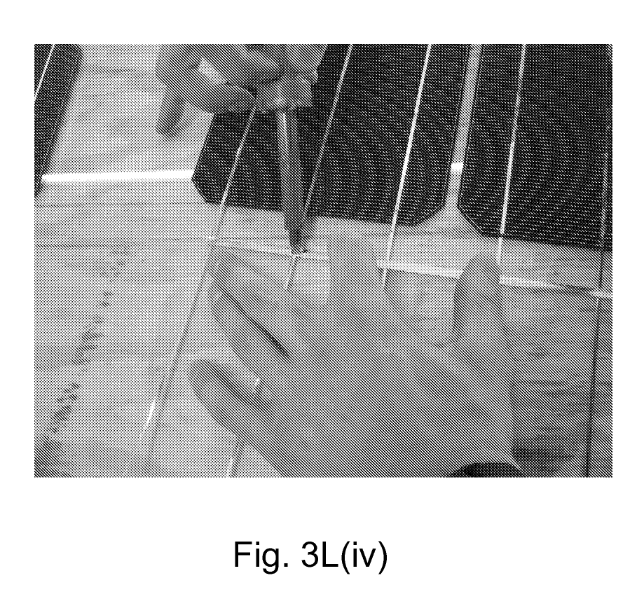

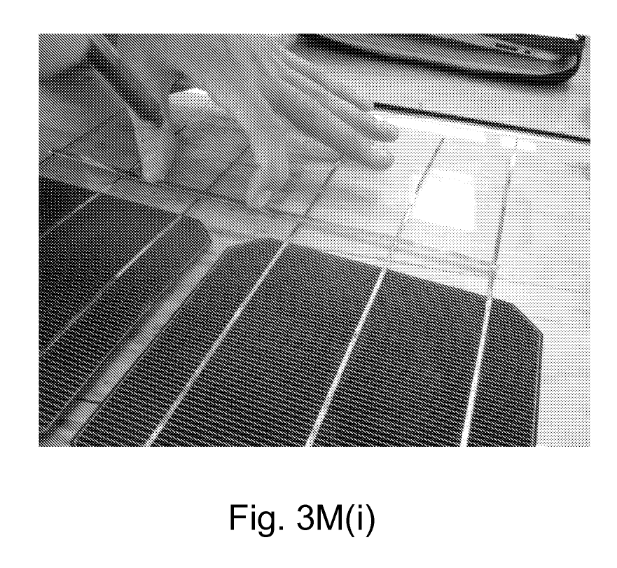

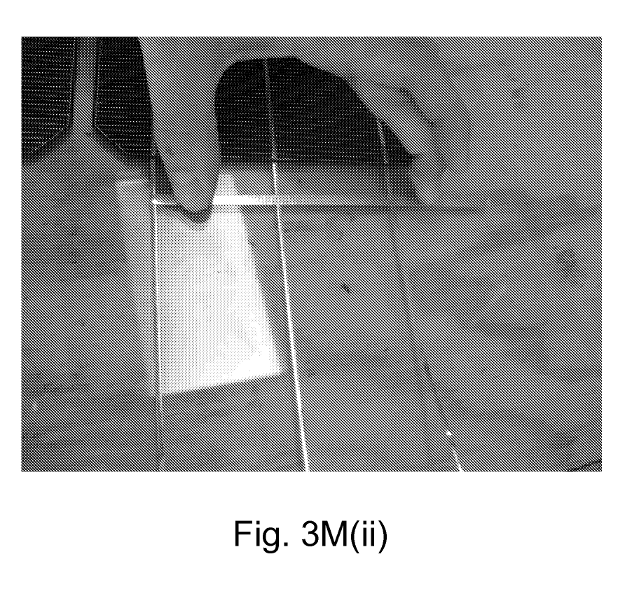

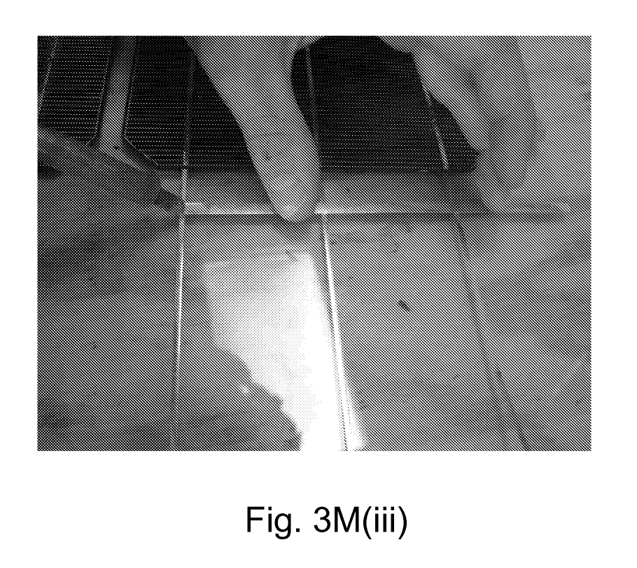

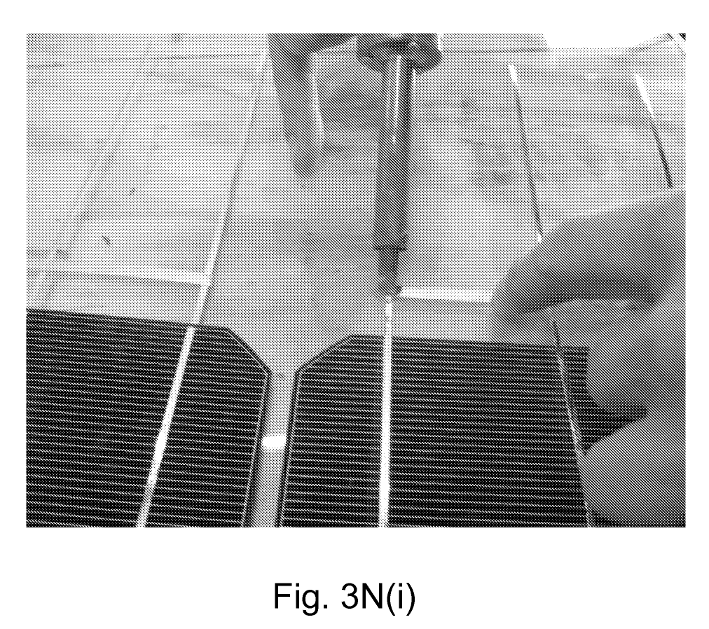

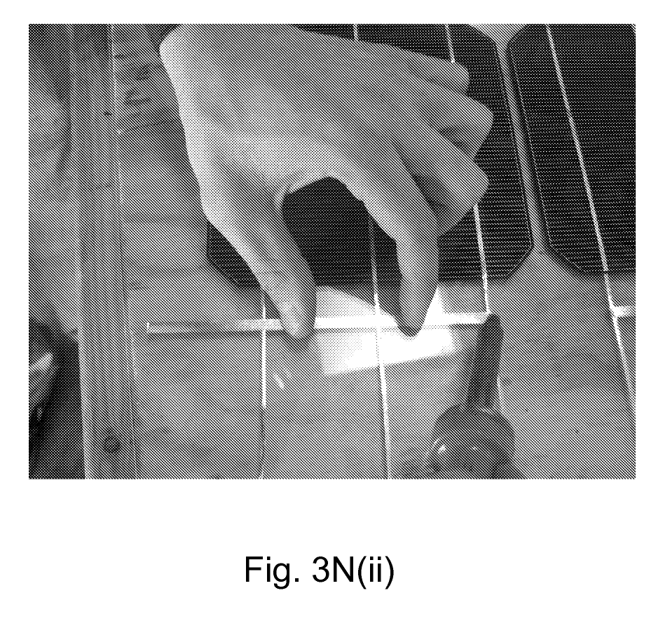

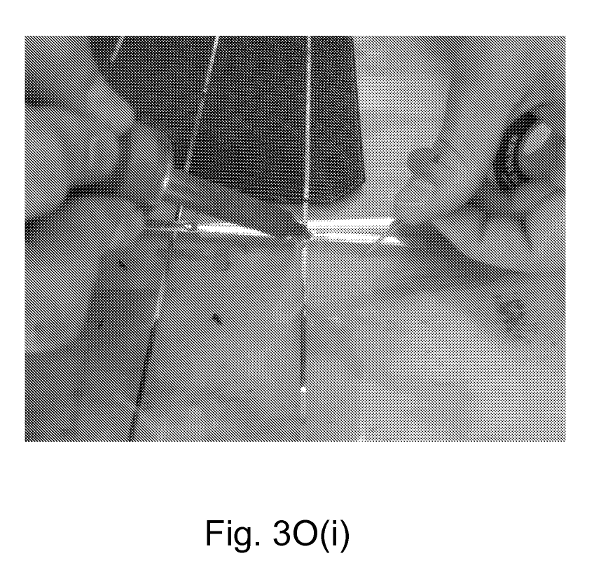

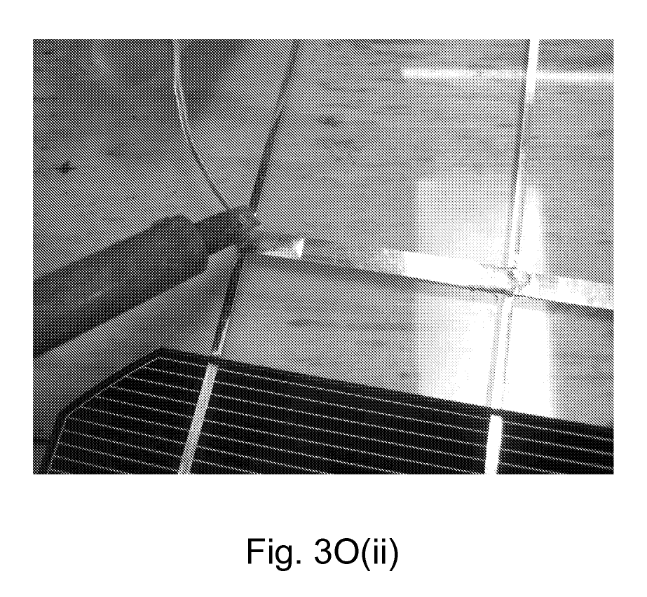

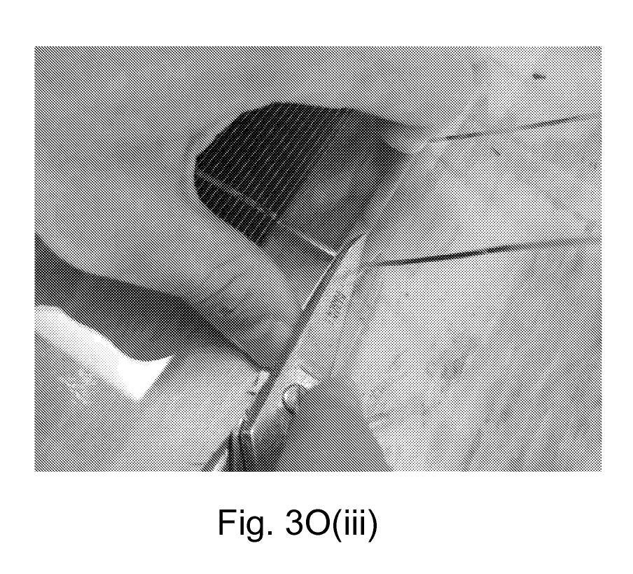

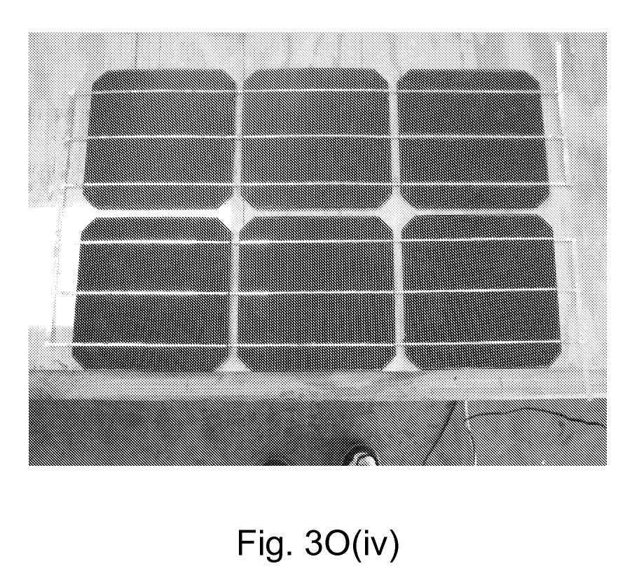

1. Acquire six Suniva Artisun 156 cells (FIG. 3A).

2. Take three cells placed face up on a clean glass table heated to 80° F. (FIG. 3B).

3. Using a flux pen, pre-flux each of the bus lines on each cell (FIG. 3C).

4. Cut* tabbing wire for each bus line at a length of 12 5/16″.

5. Using a pre heated soldering iron starting at the beginning edge of each bus line of each cell, solder the tabbing line along entire length of each bus line of each cell. Complete this process for each bus line of each front face of each cell (FIG. 3D(i-v)).

6. Turn each cell face down on heated glass table (FIG. 3E(I,ii)).

7. Using a flux pen, pre-flux each of the bus lines of each cell back (FIG. 3F).

8. Align second cell under the tabbing wires of first cell with ¼″ spacing (FIG. 3H).

9. Using a preheated soldering iron, solder tabbing wire from the front face of first cell to the back of the second cell along the bus lines stopping 1/16″ from the end of cell (FIG. 3G(I,ii)).

10. On final cell, repeat step 9 (FIG. 3I(I,ii)).

11. Cut three tabbing wires to 7″ long. Solder cut tabbing wires to the bussing lines on the back of cell with residual tabbing wire facing away from set of 3 cells (FIG. 3J(i-iii).

12. Repeat steps 1 to 11 for the additional required set of three cells (FIG. 3K).

13. Lay both sets of three cells horizontally on heated glass table face up (FIG. 3K).

14. Set a (top set) to be placed with positive tabbing wires facing left (FIG. 3K, 3L(ii)).

15. Set b (bottom set) to be placed with negative tabbing wires facing left while maintaining a ¼″ parallel spacing in relation to set a (FIGS. 3K, 3L(i)).

16. Cut bussing tape to appropriate length to cover distance of both set a and set b's tabbing wires on left (FIG. 3L(iii), FIG. 3M(i)).

17. Solder cut bus tape to each tabbing wire of set a's positive side and set b's negative side to create series (FIG. 3L(iv), FIG. 3M(i)).

18. Cut two 6″ strips of bussing tape.

19. Solder one 6″ strip of bussing tape to taping wires of set a's negative side leaving residual bussing tape facing away from both set a and set b (FIG. 3M(ii,iii)).

20. Solder remaining 6″ strip of bussing tape to taping wires of set b's positive side leaving residual bussing tape facing away from both set b and set a (FIG. 3N (i,ii)).

21. Prepping cells for encapsulation.

Other embodiments of a method for preparing a mono-crystalline cell can automate one or more of the steps and actions.

Process for Encapsulating a Mono-Crystalline Cell:

1. Uncover prepped table for encapsulation.

2. Place finished set of 6 cells face down on prepped table

3. Cut 4 pieces of carbon fiber to desired size based on number of sets being encapsulated per prepped table.

4. Cut honeycomb to 15″ by 23″ for each set of 6 cells to be encapsulated.

5. Preparing resin:

5-a. Prepare 4 ounces of resin per 17″ by 25″ area.

### 5-a-1. Pour 3 ounces of 2120 resin and 1 ounce of 2000 resin epoxy cure into mixing cup.

5-a-2. Mix thoroughly.

6. Place 1 sheet of cut dry carbon fiber on top of sets of 6 cells on prepped table.

7. Using a paint brush, apply resin mix to top of carbon fiber from the outside edge of table working inwards towards center of table.

8. Place second sheet of dry carbon fiber on top of first sheet.

9. Pour a small amount of resin in center of table over second sheet.

10. Using light pressure with a rubber flat scraper, spread poured resin from center to all outer edges of carbon fiber.

11. Place cut honeycomb with even spacing over the 2 layers of carbon fiber.

12. Place third sheet of dry carbon fiber over honeycomb.

13. Repeat steps 9 and 10 for third layer of carbon fiber.

14. Place fourth and final sheet of dry carbon fiber over third layer of carbon fiber.

15. Repeat steps 9 and 10 for fourth and final layer of carbon fiber.

Other embodiments of a method for encapsulating a mono-crystalline cell can automate one or more of the steps and actions.

Other embodiments of a method for producing a solar panel automate one or more of the steps and actions.

Process for Preparing a Table for Producing a Solar Panel:

1. Apply acetone to entire glass surface.

2. Wipe immediately until entire surface is dry.

3. Line edge of table with yellow double sided sealant tape while not removing protective layer from adhesive.

4. Apply Partall #2 wax to glass surface.

5. Immediately wipe off wax.

6. Repeat steps 4 and 5.

7. Apply a thin layer of polyvinyl alcohol (PVA) release film with air spray gun at 20 PSI.

8. Allow to dry for ten minutes.

9. Apply five thicker layers of PVA allowing ten minutes of dry time for a total of six coats of PVA.

10. Cover table to protect from dirt/dust until cells are ready to be set.

Other embodiments of a method for preparing a table can automate one or more of the steps and actions.

Process for Vacuum Sealing the Solar Panel:

1. Cut peel-ply to cover entire area of resonated carbon fiber.

2. Using light pressure with rubber flat scraper, apply peel ply to top of resonated carbon fiber.

3. Cut absorbent to same dimensions as peel ply.

4. Place absorbent gently over peel ply layer.

5. Cut 6″ by 24″ piece of absorbent.

6. Fold into a 6″ by 6″ square.

7. Place folded absorbent square on any corner of product on edge of carbon fiber.

8. Peel protective layer off of yellow double sided sealant tape on edge of table exposing adhesive.

9. Stretch vacuum bagging film over product.

10. Firmly press vacuum bagging film to yellow adhesive along edges of table.

11. Adjust vacuum pressure according to which type of cell to be sealed under vacuum*.

12. Make 1″ incision in vacuum film over 6″ by 6″ absorbent square.

13. Place vacuum fitting in 1″ incision.

14. Apply vacuum tape to vacuum bagging film surrounding vacuum fitting.

15. Tighten vacuum fitting securely.

16. Plug air line into vacuum hose.

17. Leave product under vacuum for a minimum of 8 hours**.* 22 PSI for mono crystalline cells, 120 PSI for thin film cells.**

Table is to be maintained at 80° F. during processing of the solar panel.

Other embodiments of a method for vacuum sealing can automate one or more of the steps and actions.

Process for Removing Product (Solar Panels) from the Table:

1. Unplug vacuum airline.

2. Cut vacuum airline from vacuum film.

3. Remove vacuum film from product.

4. Pull peel ply with absorbent on top from product.

5. Using rubber flat scraper, gently peel edges of product up while using air nozzle set to 120 PSI to help remove product smoothly and cleanly from table.

Other embodiments of a method for removing product can automate one or more of the steps and actions.

Terms “substantially”, “essentially”, or “approximately”, that may be used herein, relate to an industry-accepted variability to the corresponding term. Such an industry-accepted variability ranges from less than one percent to twenty percent and corresponds to, but is not limited to, materials, shapes, sizes, functionality, values, process variations, and the like. The term “coupled”, as may be used herein, includes direct coupling and indirect coupling via another component or element where, for indirect coupling, the intervening component or element does not modify the operation. Inferred coupling, for example where one element is coupled to another element by inference, includes direct and indirect coupling between two elements in the same manner as “coupled”.

The illustrative pictorial diagrams depict structures and process actions in a manufacturing process. Although the particular examples illustrate specific structures and process acts, many alternative implementations are possible and commonly made by simple design choice. Manufacturing actions may be executed in different order from the specific description herein, based on considerations of function, purpose, conformance to standard, legacy structure, and the like.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, shapes, and dimensions are given by way of example only. The parameters, materials, and dimensions can be varied to achieve the desired structure as well as modifications, which are within the scope of the claims. Variations and modifications of the embodiments disclosed herein may also be made while remaining within the scope of the following claims.

What is claimed is:

1. A solar powered vest comprising:
a body garment;
a solar collector mounted on the body garment; and
a power interface coupled to the solar collector operable to store power collected from the solar collector and distribute power to rechargeable devices that can be connected to the power interface.

2. The solar powered vest according to claim 1 wherein the solar collector comprises:
a carbon fiber sheet; and
at least one monocrystalline cell mounted to the carbon fiber sheet.

3. The solar powered vest according to claim 2 wherein the solar collector comprises:
a carbon fiber sheet;
a plurality of solar cells mounted on the carbon fiber sheet; and
a coating applied in multiple layers on the plurality of solar cells and the carbon fiber sheet.

4. The solar powered vest according to claim 1 further comprising:
a lithium polymer battery coupled to the solar collector and operable to store solar-generated electrical charge.

5. The solar powered vest according to claim 1 wherein the power interface comprises:
a power management apparatus.

6. The solar powered vest according to claim 5 wherein the management apparatus comprises:
at least one power output connector operable to supply power to powered devices characterized by a plurality of power characteristics; and
at least one power control circuit operable to determine a power characteristic of a powered device connected to the at least one power output connector and to supply power to the powered device in compliance with the power characteristic.

7. The solar powered vest according to claim 5 wherein the management apparatus comprises:
the at least one power output connector comprises at least one Universal Serial Bus (USB) connector.

8. The solar powered vest according to claim 5 wherein the management apparatus comprises:
the at least one power output connector comprises at least one connector jack.

9. The solar powered vest according to claim 5 wherein the management apparatus comprises:
the at least one power output connector comprises at least one audio output jack.

10. The solar powered vest according to claim 5 wherein the management apparatus comprises:
the at least one power output connector comprises at least one Universal Serial Bus (USB) connector and at least one connector jack.

11. The solar powered vest according to claim 5 wherein the management apparatus comprises:
the at least one power output connector comprises at least one output connector operable to connect a plurality of powered devices in series.

12. The solar powered vest according to claim 5 wherein the management apparatus comprises:
the power input connector is operable for connecting to a solar power source.

13. The solar powered vest according to claim 5 wherein the management apparatus comprises:
the power input connector is operable for connecting to a battery.

14. The solar powered vest according to claim 5 wherein the management apparatus comprises:
the at least one power control circuit is operable to determine a power requirement of a powered device connected to the at least one power output connector and to regulate power to the determined power requirement.

15. The solar powered vest according to claim 14 wherein the management apparatus comprises:
the at least one power control circuit comprises blocking diodes operable to restrict power for charging the powered device.

16. The solar powered vest according to claim 5 wherein the management apparatus comprises:
the at least one power control circuit is operable to determine a voltage requirement of a powered device connected to the at least one power output connector and to regulate voltage to the determined requirement.

17. The solar powered vest according to claim 5 wherein the management apparatus comprises:
the at least one power control circuit is operable to determine a current requirement of a powered device connected to the at least one power output connector and to regulate current to the determined requirement.
